(19) United States
(12) Patent Application Publication
(10) Pub. No.: US 2018/0261621 A1
(43) Pub. Date: Sep. 13, 2018

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Sheng-Hong Chen, Kaohsiung City (TW); Ting-Feng Liao, New Taipei City (TW)

(21) Appl. No.: 15/455,185

(22) Filed: Mar. 10, 2017

(51) Int. Cl. H01L 27/11582; H01L 23/522; H01L 23/532; H01L 23/528; H01L 21/768

(52) U.S. Cl. CPC H01L 27/11582; H01L 23/5226; H01L 21/76877; H01L 23/5283; H01L 21/76831; H01L 23/5329

(57) ABSTRACT

A semiconductor structure includes a substrate and a plurality of sub-array structures disposed on the substrate. The sub-array structures separated from each other by a plurality of trenches. The semiconductor structure includes a three-dimensional array of memory cells. The memory cells include a plurality of cell groups disposed in the sub-array structures, respectively. The semiconductor structure further includes a plurality of support pillars and a plurality of conductive pillars disposed in the trenches. The support pillars and the conductive pillars in each of the trenches are alternately arranged in an extending direction of the trenches. The semiconductor structure further includes a plurality of conductive lines disposed in the trenches and on the support pillars and the conductive pillars. Each of the conductive lines connects the conductive pillars thereunder.

### TECHNICAL FIELD

This disclosure relates to a semiconductor structure and a method for manufacturing the same. More particularly, this disclosure relates to a semiconductor structure comprising memory cells and a method for manufacturing the same.

### BACKGROUND

For reasons of decreasing volume and weight, increasing power density, improving portability and the like, three-dimensional (3-D) semiconductor structures have been developed. In addition, elements arid spaces in a semiconductor device have continuously been shrunk. This may cause some problems. For example, in a manufacturing process for a 3-D memory device, stacks having a high aspect ratio may be formed for the construction of memory cells and/or other components. Such a stack may bend or collapse due to its high aspect ratio. As such, various improvements for the semiconductor structures and the methods for manufacturing them are still desired.

### SUMMARY

This disclosure is directed to semiconductor structures and methods for manufacturing the same, and particularly to a semiconductor structure comprising memory cells and a method for manufacturing the same.

According to some embodiments, a semiconductor structure comprises a substrate and a plurality of sub-array structures disposed on the substrate. The sub-array structures separated from each other by a plurality of trenches. The semiconductor structure comprises a three-dimensional array of memory cells. The memory cells comprise a plurality of cell groups disposed in the sub-array structures, respectively. The semiconductor structure further comprises a plurality of support pillars and a plurality of conductive pillars disposed in the trenches. The support pillars and the conductive pillars in each of the trenches are alternately arranged in an extending direction of the trenches. The semiconductor structure further comprises a plurality of conductive lines disposed in the trenches and on the support pillars and the conductive pillars. Each of the conductive lines connects the conductive pillars thereunder.

According to some embodiments, a method for manufacturing a semiconductor structure comprises the following steps. First, an initial structure is provided. The initial structure comprises a substrate and a preliminary array structure formed on the substrate. The preliminary array structure comprises a stack and a plurality of active structures penetrating through the stack. Each of the active structures comprises a channel layer and a memory layer formed between the channel layer and the stack. A plurality of support pillars are formed in predetermined trench positions for a plurality of trenches configured for separating the preliminary array structure into a plurality of sub-array structures. The support pillars are separated from each other in each of the predetermined trench positions. Then, a plurality of conductive pillars are formed in the predetermined trench positions such that the conductive pillars and the support pillars in each of the predetermined trench positions are alternately arranged in an extending direction of the predetermined trench positions. A plurality of conductive lines are formed on the support pillars and the conductive pillars.

### BRIEF DESCRIPTION OF THE DRAWINGS

FIGS. 1A-1C illustrate a semiconductor structure according to embodiments.

FIGS. 2A-13C illustrate a method for manufacturing a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The accompanying drawings are provided for illustrative and explaining purposes rather than a limiting purpose. For clarity, the elements may not be drawn to scale. In addition, some components and/or reference numerals may be omitted from some drawings. It is contemplated that the elements and features of one embodiment can be beneficially incorporated in another embodiment without further recitation.

A semiconductor structure according to embodiments comprises a substrate and a plurality of sub-array structures disposed on the substrate. The sub-array structures separated from each other by a plurality of trenches. The semiconductor structure comprises a three-dimensional array of memory cells. The memory cells comprise a plurality of cell groups disposed in the sub-array structures, respectively. The semiconductor structure further comprises a plurality of support pillars and a plurality of conductive pillars disposed in the trenches. The support pillars and the conductive pillars in each of the trenches are alternately arranged in an extending direction of the trenches. The semiconductor structure further comprises a plurality of conductive lines disposed in the trenches and on the support pillars and the conductive pillars. Each of the conductive lines connects the conductive pillars thereunder.

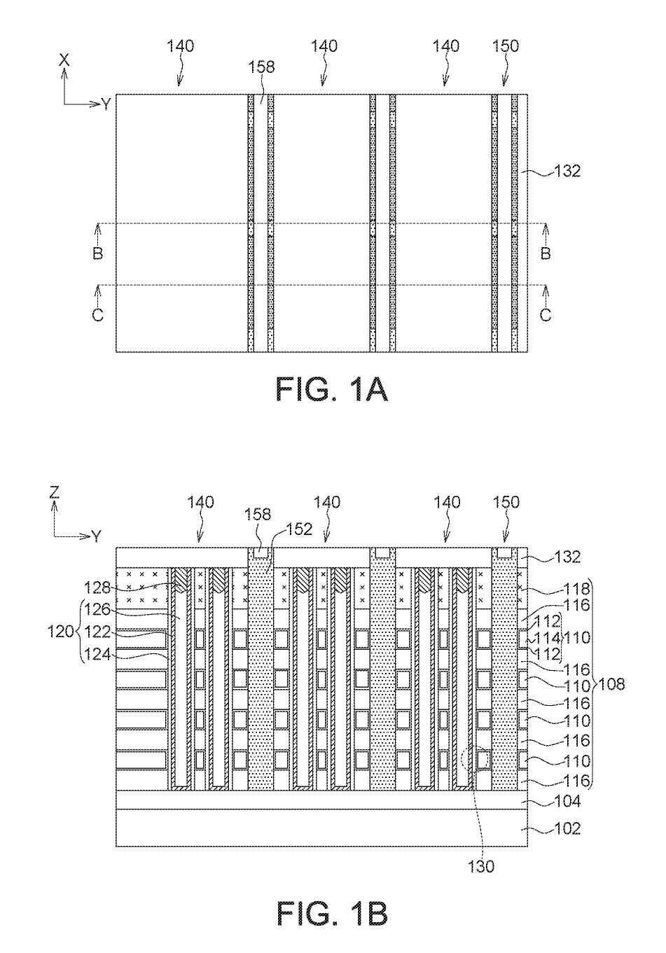

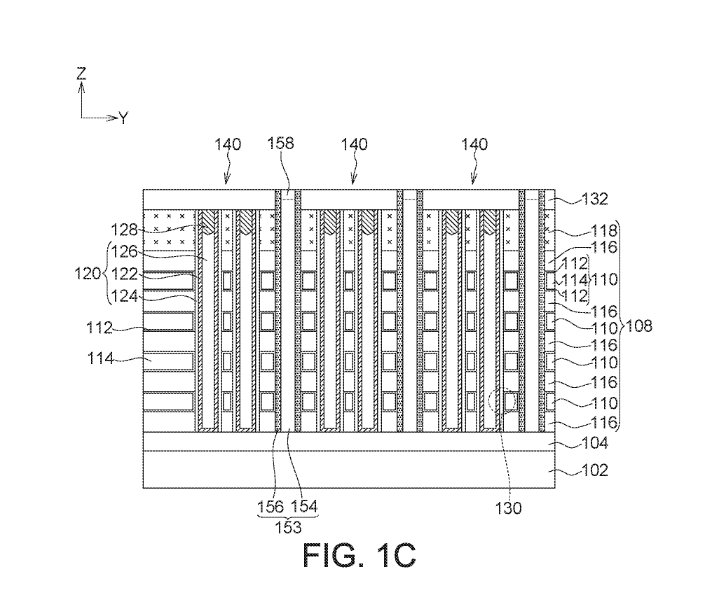

Referring to FIGS. 1A-1C, such a semiconductor structure is shown. In the accompanying drawings, for ease of understanding, the semiconductor structure is illustrated as a 3-D vertical channel NAND memory structure.

The semiconductor structure comprises a substrate 102. The substrate 102 may comprise structures, components, and the like formed therein and/or thereon. For example, the substrate 102 may comprise a buried layer 104 disposed thereon

The semiconductor structure comprises a plurality of sub-array structures 140 disposed on the substrate 102. The sub-array structures 140 are separated from each other by a plurality of trenches 150. According to some embodiments, each sub-array structure 140 may comprises a stack 108 and one or more active structures 120 penetrating through the stack 108. While FIGS. 1A-1C illustrate the example that each cell group comprises two rows of the active structures 120, the embodiments are not limited thereto. The stack 108 comprises alternately stacked conductive layers 110 and insulating layers 116. In some embodiments, each conductive layer 110 comprises two high-k dielectric layers 112 and a conductive core layer 114 disposed therebetween, as shown in FIG. 1B. In such cases, the conductive core layer 114 may be formed of a metal material. The two high-k dielectric layers 112 may be connected with each other. In some other embodiments, each conductive layer 110 may be composed of a single layer. In such cases, the conductive core layer 114 may be formed of doped-polysilicon. In some embodiments, the stack 108 further comprises a hard mask layer 118 disposed on the conductive layers 110 and the insulating layers 116. According to some embodiments, each active structure 120 may be formed in a column-type configuration. In such cases, each active structure 120 may comprise a channel layer 122 and a memory layer 124 disposed between the channel layer 122 and the stack 108. In some embodiments, each active structure 120 further comprises an insulating material 126 filled in a space formed by the channel layer 122. In some embodiments, each sub-array structure 140 further comprises one or more conductive pads 128 coupled to the one or more active structures 120, respectively. In some embodiments, each sub-array structure 140 further comprises an interlayer dielectric layer 132 disposed on the stack 108. According to some embodiments, the sub-array structures 140 may have a high aspect ratio.

The semiconductor structure comprises a plurality of support pillars 152 and a plurality of conductive pillars 153 disposed in the trenches 150. The support pillars 152 and the conductive pillars 153 in each trench 150 are alternately arranged in an extending direction of the trenches 150 (the X-direction in the drawings). According to some embodiments, the support pillars 152 may be formed of an insulating material, such as an oxide material. According to some embodiments, each conductive pillar 153 may comprise a conductive center portion 154 and an insulating liner layer 156 surrounding the conductive center portion 154. The semiconductor structure further comprises a plurality of conductive lines 158 disposed in the trenches 150 and on the support pillars 152 and the conductive pillars 153. Each conductive line 158 connects the conductive pillars 153 thereunder. In some embodiments, the conductive lines 158 and the conductive pillars 153 are formed of the same material.

The semiconductor structure comprises a three-dimensional array of memory cells 130. The memory cells 130 comprise a plurality of cell groups (not indicated in the drawings) disposed in the sub-array structures 140, respectively. More specifically, the memory cells 130 in the cell group disposed in the each sub-array structure 140 can be defined by cross points between the conductive layers 110 of the stack 108 and the one or more active structures 120. According to some embodiments, the conductive layers 110 of the stacks 108 of the sub-array structures 140 may be configured for word lines, the conductive pads 128 of the sub-array structures 140 may be configured for bit lines, and the conductive pillars 153 and the conductive lines 158 may be configured for common source lines.

Now the description is directed to a method for manufacturing a semiconductor structure according to embodiments. It comprises the following steps. First, an initial structure is provided. The initial structure comprises a substrate and a preliminary array structure formed on the substrate. The preliminary array structure comprises a stack and a plurality of active structures penetrating through the stack. Each of the active structures comprises a channel layer and a memory layer formed between the channel layer and the stack. A plurality of support pillars are formed in predetermined trench positions for a plurality of trenches configured for separating the preliminary array structure into a plurality of sub-array structures. The support pillars are separated from each other in each of the predetermined trench positions. Then, a plurality of conductive pillars are formed in the predetermined trench positions such that the conductive pillars and the support pillars in each of the predetermined trench positions are alternately arranged in an extending direction of the predetermined trench positions. A plurality of conductive lines are formed on the support pillars and the conductive pillars.

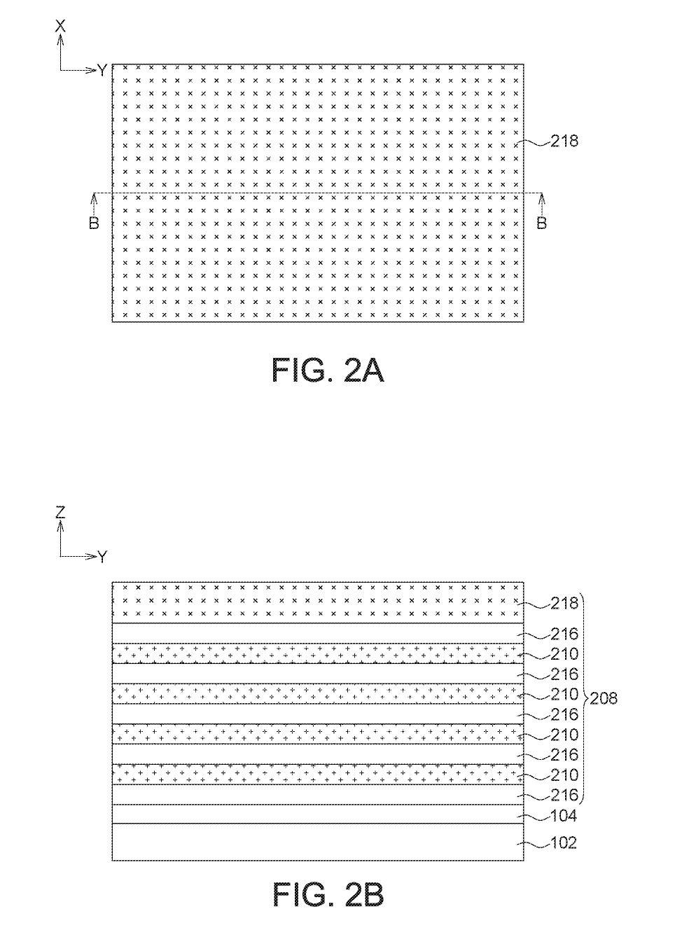

Referring to FIGS. 2A-13C, such a method is illustrated. For ease of understanding, the method is illustrated to form the semiconductor structure as shown in FIGS. 1A-1C applying a process using sacrificial layers, which will be replaced with conductive layers in the following steps. The figures identified by “B” and “C” show cross-sections taken along the line B-B and the line C-C in the figures identified “A”, respectively.

As shown in FIGS. 2A-2B, a substrate 102 is provided. The substrate 102 may comprise structures, components, and the like formed therein and/or thereon. For example, the substrate 102 may comprise a buried layer 104 disposed thereon, as shown in FIG. 2B. The buried layer 104 may be formed of oxide. A stack 208 is formed on the substrate 102. The stack 208 comprises alternately stacked sacrificial layers 210 and insulating layers 216. The sacrificial layers 210 may be formed of silicon nitride (SiN). The insulating layers 216 may be formed of oxide. In some embodiments, as shown in FIGS. 2A-2B, the stack 208 further comprises a hard mask layer 218 formed on the sacrificial layers 210 and the insulating layers 216, which is used to compensate the film stress and prevent the stack collapse or bending.

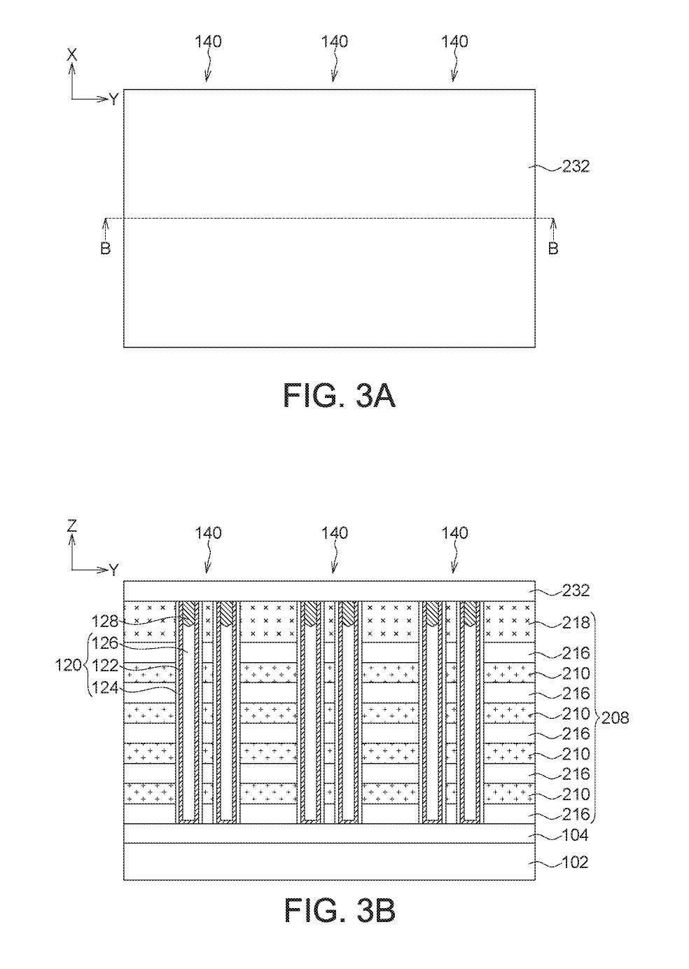

As shown in FIGS. 3A-3B, a plurality of active structures 120 are formed through the stack 208. More specifically, in some embodiments, a plurality of holes may be formed through the stack 208. A plurality of memory layers 124 may be formed on sidewalls of the holes, respectively. The memory layers 124 may have multi-layer structures, such as ONO (oxide/nitride/oxide), ONONO (oxide/nitride/oxide/nitride/oxide) or the like. A plurality of channel layers 122 may be formed on the memory layers 124, respectively. The channel layers 122 may be also formed on bottoms of the holes. The channel layers 122 may be formed of polysilicon. An insulating material 126 may be filled into remaining spaces of the holes. In some embodiments, a plurality of conductive pads 128 are formed on the insulating material 126 in the holes. Each of them is coupled to the corresponding active structure 120, particularly to the channel layer 122 thereof. Then, an interlayer dielectric layer 232 may be formed on the stack 208 and the active structures 120.

As such, said “initial structure” is formed. The initial structure comprises a substrate 102 and a preliminary array structure formed on the substrate 102, wherein the preliminary array structure comprises a plurality of sub-array structures 140 that will be separated in the following steps. The preliminary array structure comprises a stack 208 and a plurality of active structures 120 penetrating through the stack 108. Each active structure 120 comprises a channel layer 122 and a memory layer 124 formed between the channel layer 122 and the stack 208. In some embodiments, the preliminary array structure further comprises a plurality of conductive pads 128 coupled to the active structures 120, respectively. In some embodiments, the preliminary array structure further comprises an interlayer dielectric layer 232 formed on the stack 208.

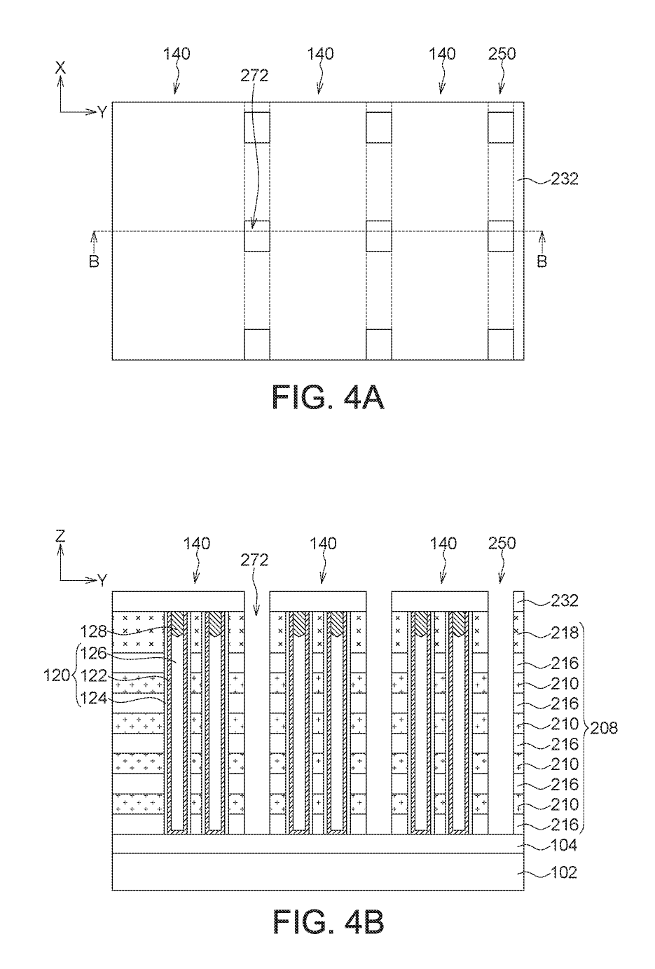

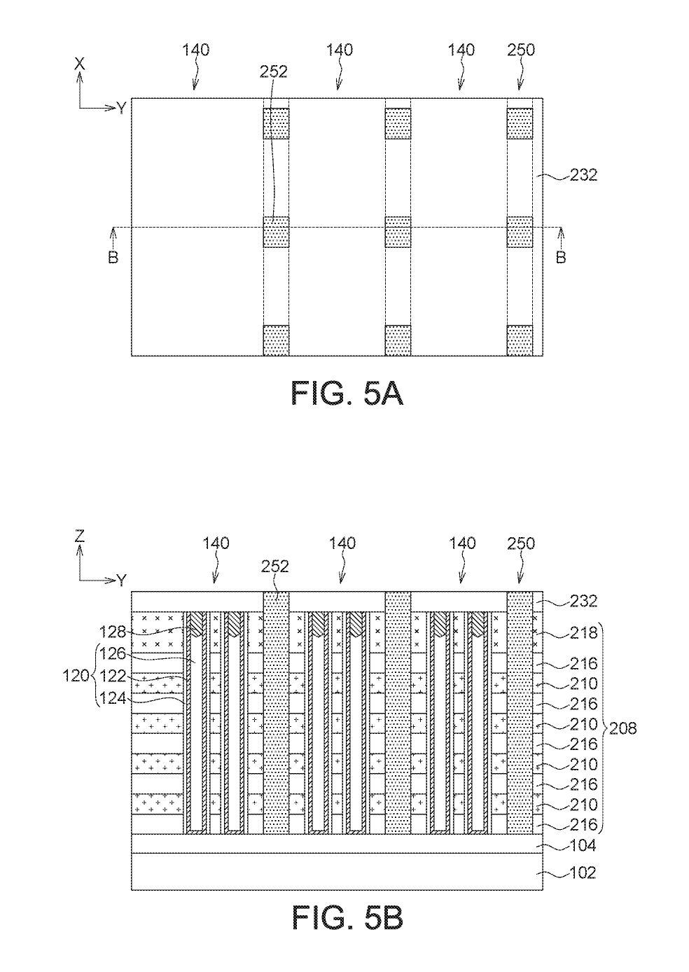

As shown in FIGS. 4A-4B, a plurality of first openings 272 are formed in predetermined trench positions 250 for a plurality of trenches 150 configured for separating the preliminary array structure into the sub-array structures 140. As shown in FIGS. 5A-5B, a first insulating material is then filled into the first openings 272. A planarization process, such as a chemical-mechanical planarization (CMP) process, may be carried out while needed. The first insulating material is a material different from the material used in the sacrificial layers 210. For example, the first insulating material may be an oxide material, such as an oxide material formed by a plasma-enhanced process. As such, a plurality of support pillars 252 are formed in the predetermined trench positions 250, wherein the support pillars 252 are separated from each other in each predetermined trench position 250.

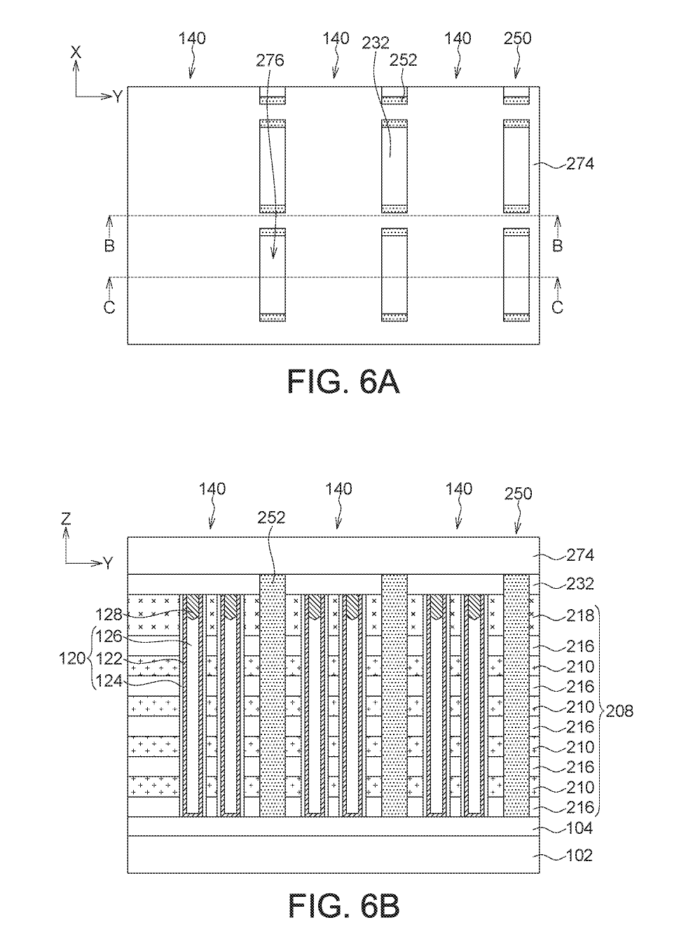

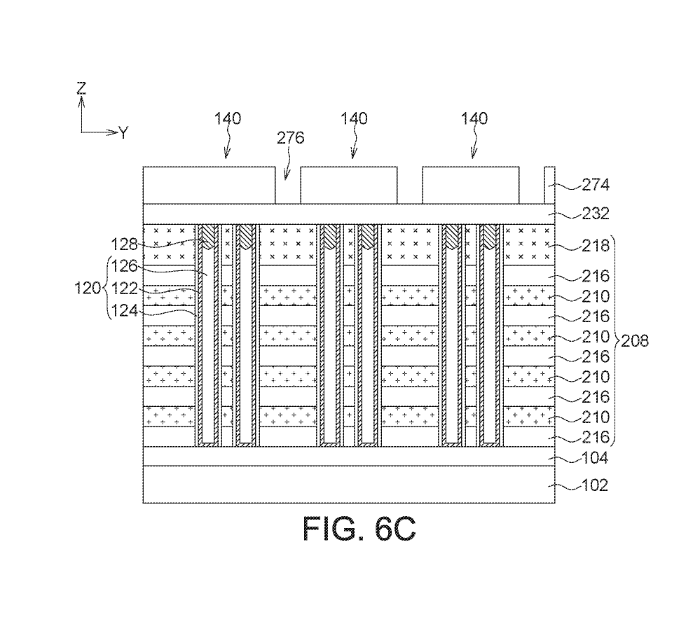

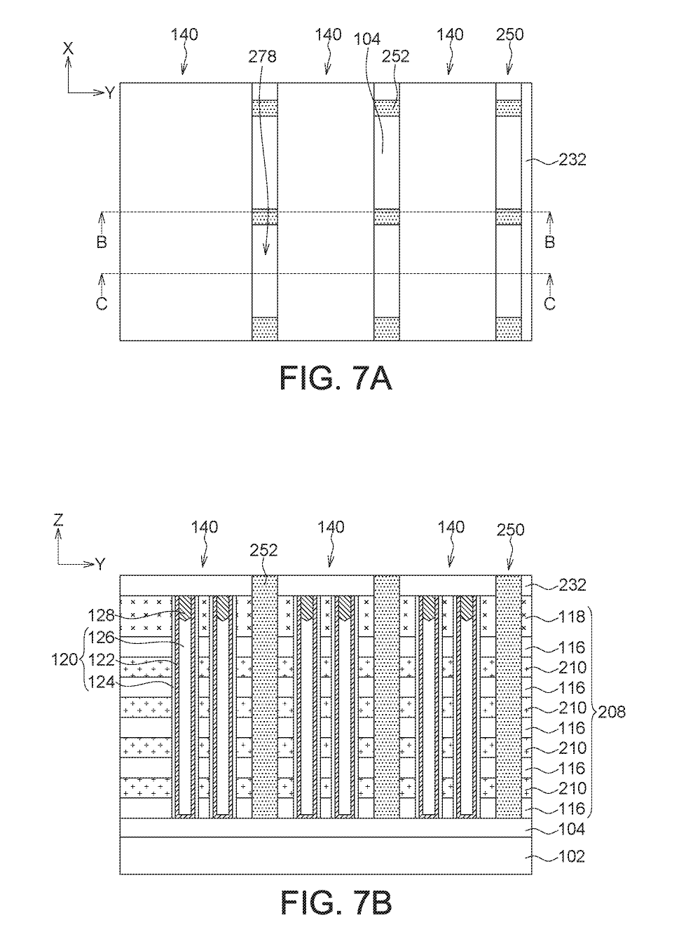

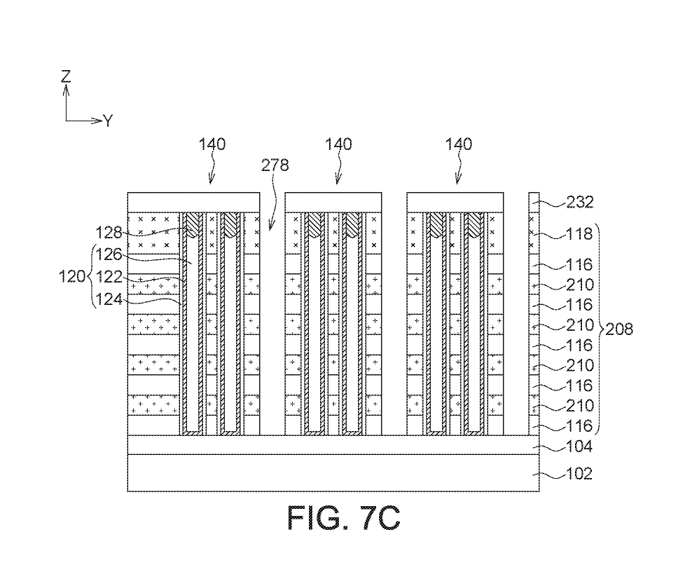

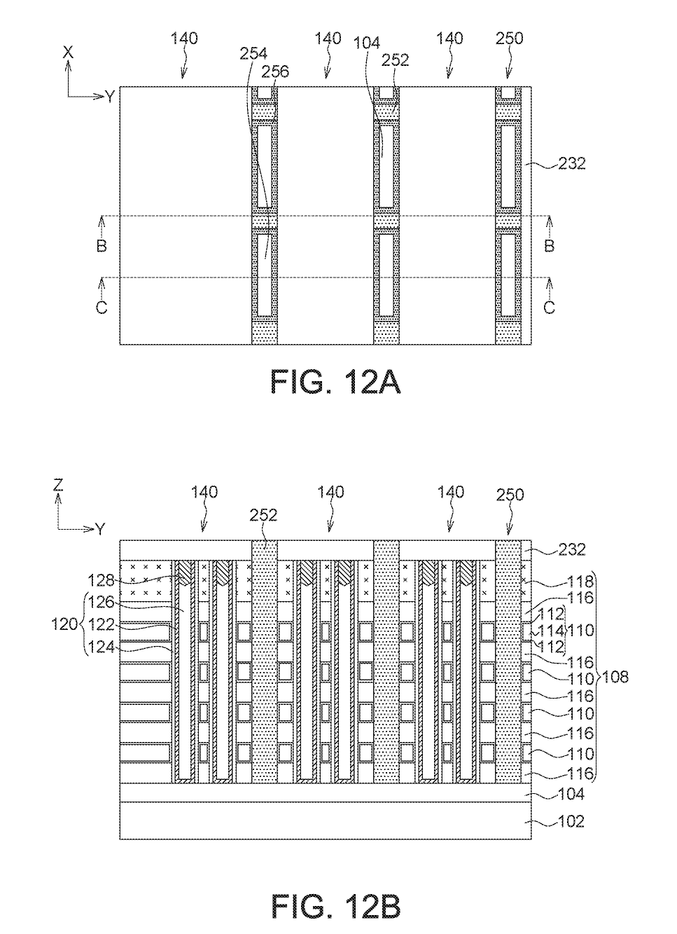

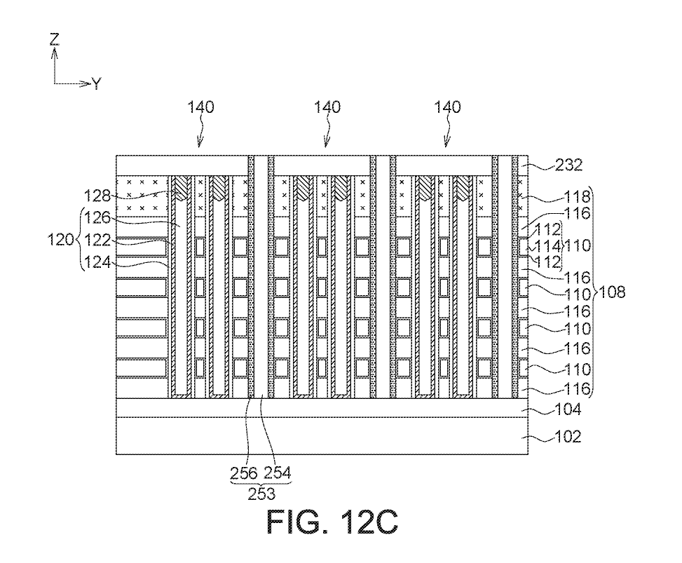

After forming the support pillars 252, as shown in FIGS. 6A-6C, a photo resist layer 274 is formed on the structures of FIGS. 5A-5B. The photo resist layer 274 comprises a plurality of holes 276 corresponding the formation of a plurality of second openings 278, which are used to form a plurality of conductive pillars 253 (FIGS. 12A-12C) in remaining portions of the predetermined trench positions 250. In some embodiments, the holes 276 expose portions of the support pillars 252 to ensure portions of the preliminary array structure in the predetermined trench positions 250 will be completely removed. Then, as shown in FIGS. 7A-7C, the plurality of second openings 278 are formed in the predetermined trench positions 250 between the support pillars 252 using the photo resist layer 274, such as by an etching process.

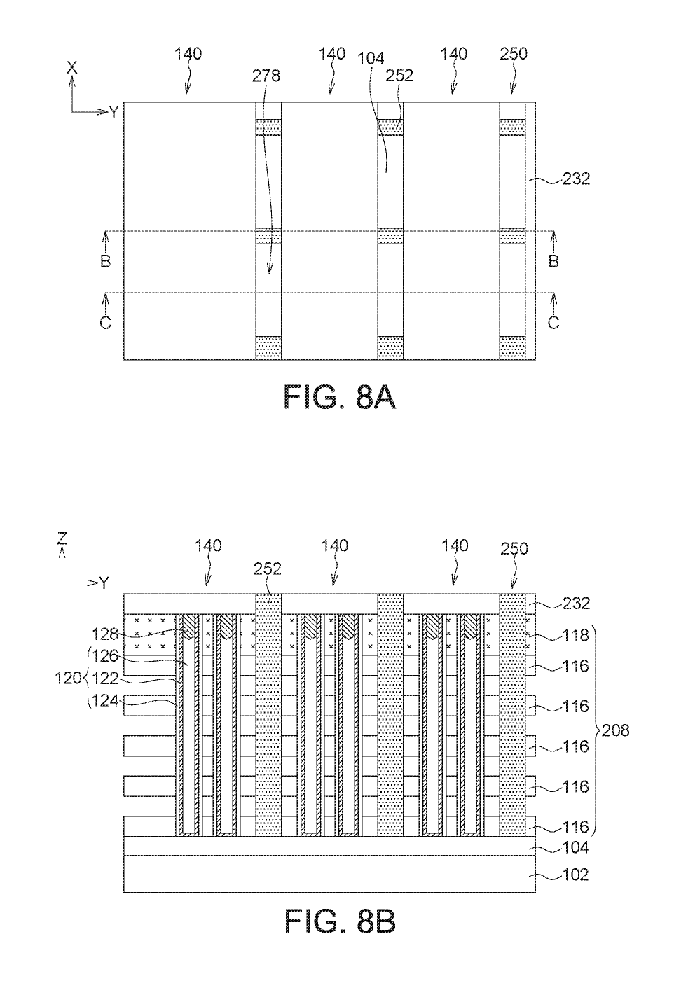

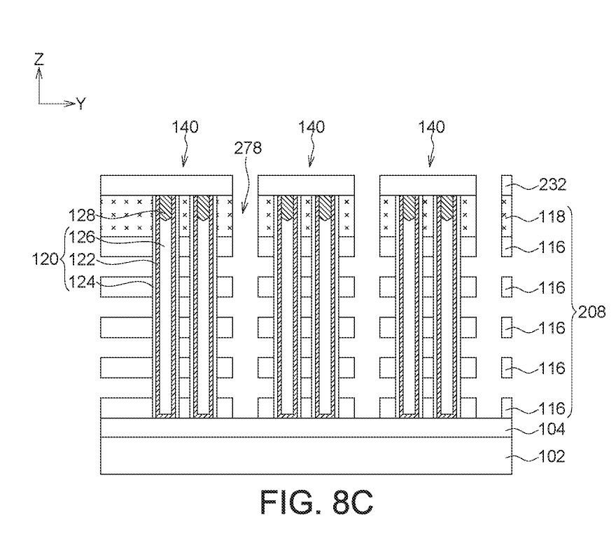

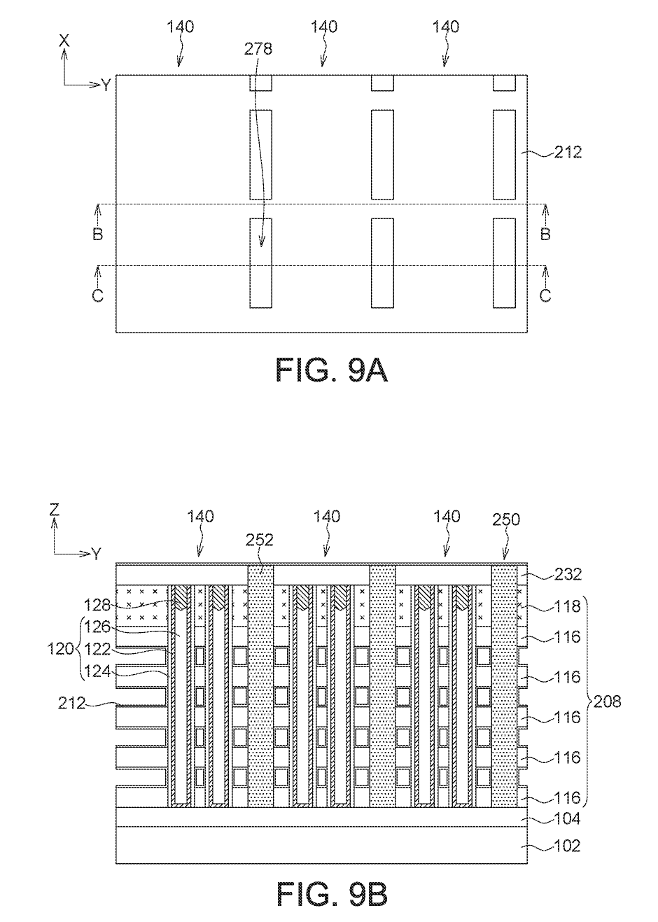

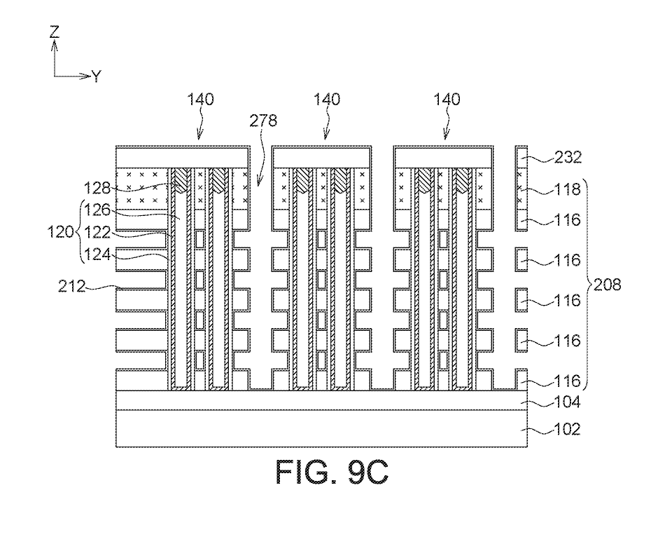

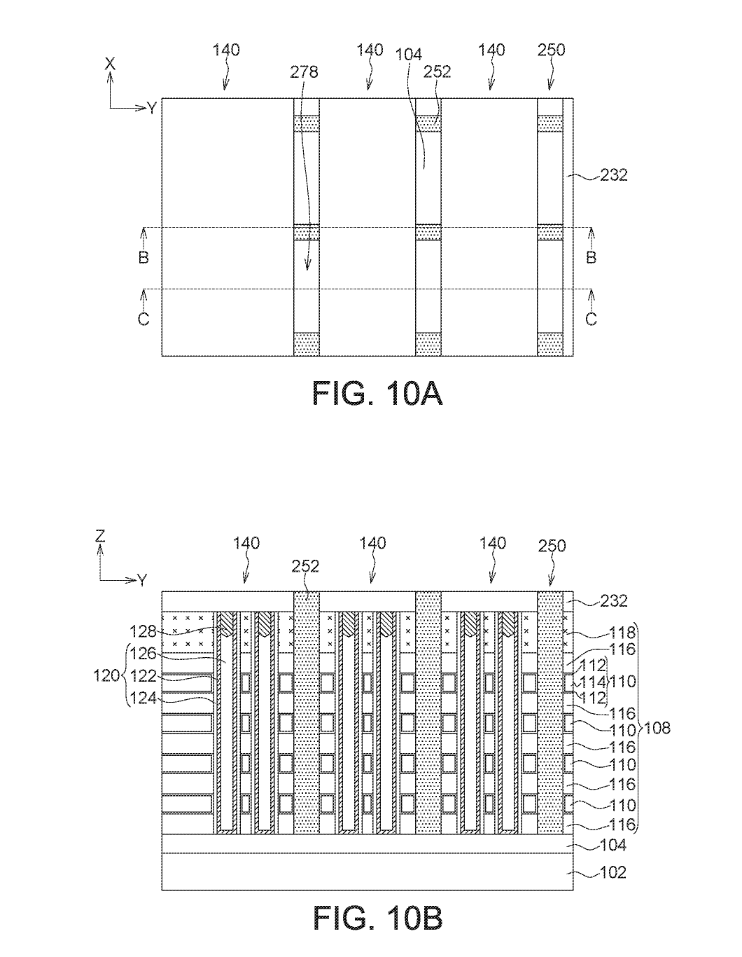

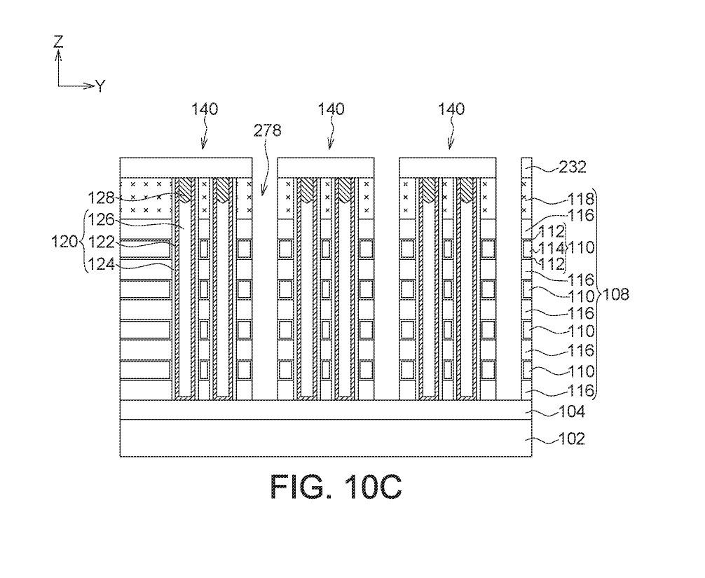

Before filling a first conductive material into the second openings 278 for the formation of the conductive pillars 253, a process of replacing the sacrificial layers 210 with conductive layers 110 may be carried out using the second openings 278. As shown in FIGS. 8A-8C, the sacrificial layers 210 are removed through the second openings 278, such as by an etching process using hot phosphoric acid (HF). As shown in FIGS. 9A-9C, high-k dielectric layers 212 are formed on top sides and bottom sides of the insulating layers 116. For example, a high-k dielectric material may be formed on the structure of FIGS. 8A-8C in a conformal manner, as shown in FIGS. 9A-9C. The high-k dielectric material may be Al₂O₃ or the like. Then, as shown in FIGS. 10A-10C, a second conductive material is filled into remaining portions of spaces produced by removing the sacrificial layers 210. The second conductive material may be tungsten (W). As such, the stacks 108 as shown in FIGS. 1A-1C are formed. In addition, unneeded portions of the high-k dielectric material are removed.

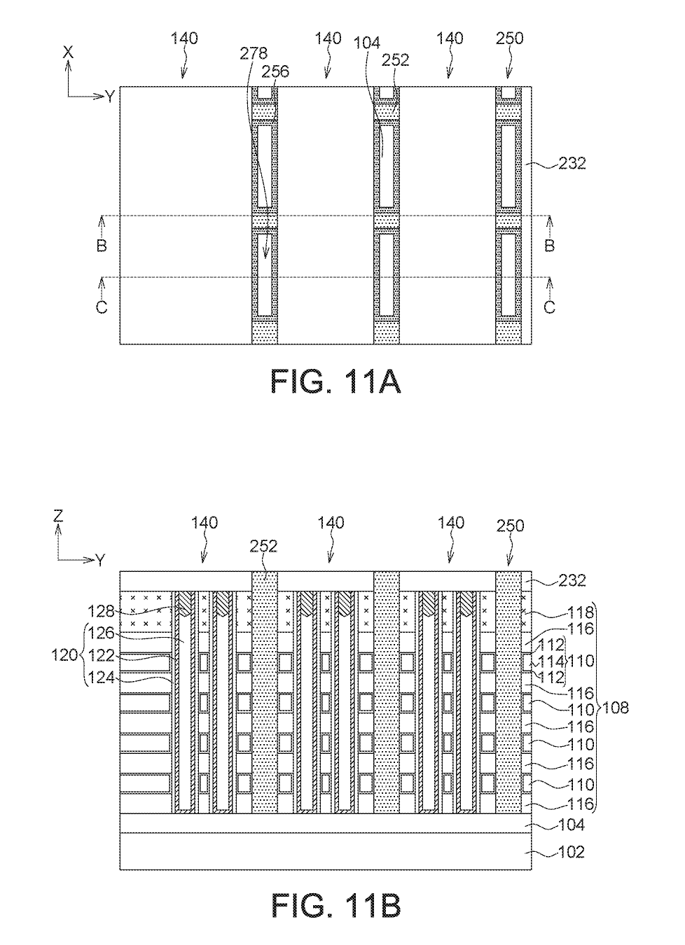

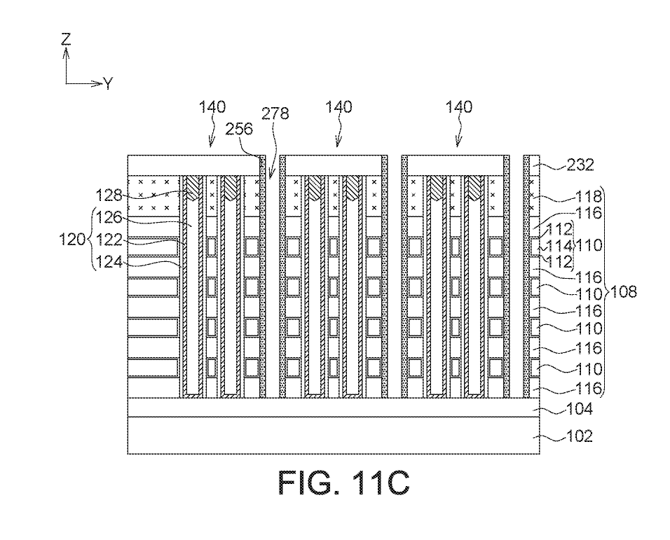

As shown in FIGS. 11A-11C, insulating liner layers 256 may be formed in the second openings 278, respectively, using a second insulating material. The second insulating material may be the same as or different from the first insulating material used to form the support pillars 252. For example, the second insulating material may be an oxide material. As shown in FIGS. 12A-12C, the first conductive material is filled into the second openings 278. As such, conductive center portions 254 of the conductive pillars 253 are formed and isolated from the conductive layers 110 by the insulating liner layers 256. The first conductive material may be tungsten (W). Thereby, the conductive pillars 253 each comprising an insulating liner layer 256 and a conductive center portion 254 are formed in the predetermined trench positions 250, such that the conductive pillars 253 and the support pillars 252 in each predetermined trench position 250 are alternately arranged in an extending direction of the predetermined trench positions 250 (the X-direction in the drawings). In some embodiments, the first conductive material is also used to form a plurality of conductive lines 158 in the following step.

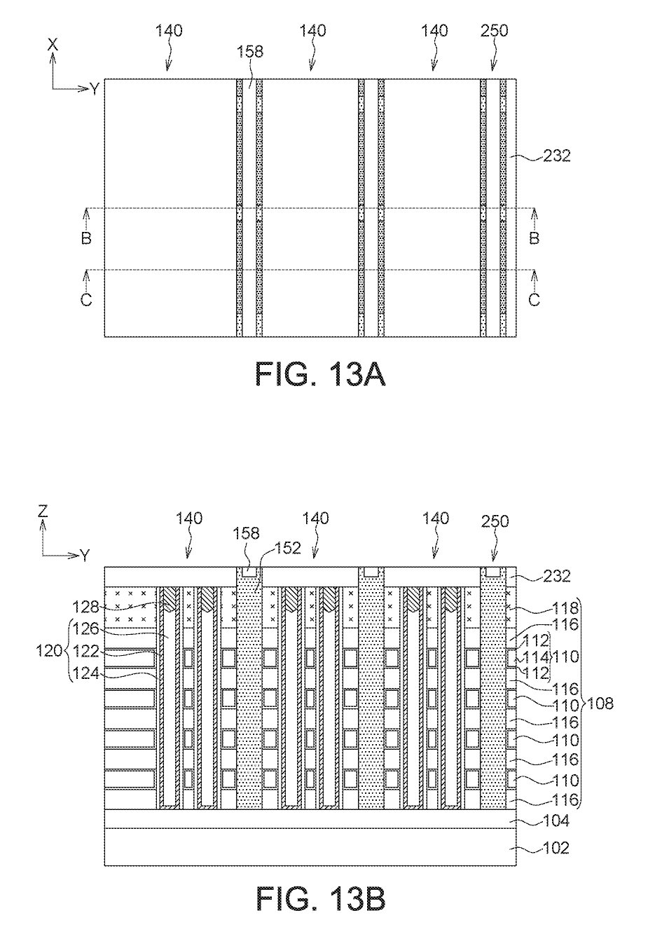

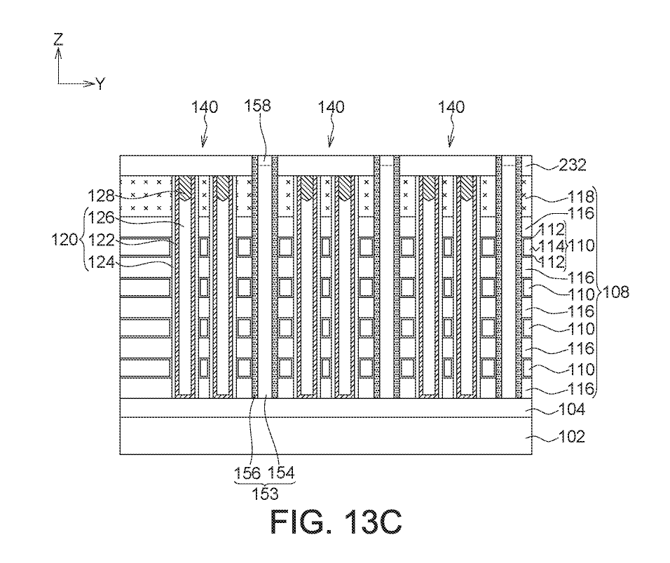

As shown in FIGS. 13A-13C, a plurality of conductive lines 158 are formed on the support pillars (252) and the conductive pillars (253), such as using tungsten (W). In some embodiments, conductive connecting layers are formed in top portions of the support pillars 252. As such, these conductive connecting layers and top portions of the conductive pillars 253 connected thereby constitute the conductive lines 158. Remaining portions of the support pillars 252 and the conductive pillars 253 are the support pillars 152 and the conductive pillars 153 as shown in FIGS. 1A-1C. In some other embodiments, a plurality of conductive lines 158 can be directly deposited on the support pillars 252 and the conductive pillars 253.

Thereafter, other processes typically used for manufacturing a semiconductor structure, such as BEOL processes, may be carried out. For example, in the BEOL processes, word lines are defined using the conductive layers 110, bit lines are defined using the conductive pads 128, common source lines are defined using the conductive pillars 153 and the conductive lines 158, and memory cells 130 are defined by cross points between the word lines and the channel layers 122.

In the method described above, since the support pillars are formed and long trenches are not directly formed in the manufacturing process, a mechanical support can be provided to stacks having a high aspect ratio, and thereby the sloping of the stacks can be prevented. Furthermore, a dislocation of contacts formed in the BEOL processes due to the sloping of the stacks can be prevented. While the forgoing examples are illustrated using a 3-D vertical channel NAND memory structure and a method applying a process using sacrificial layers, the embodiments are not limited thereto. The concepts described here can be applied to other methods for manufacturing semiconductor structures in which stacks having a high aspect ratio are formed and the semiconductor structures manufactured by the methods.

It will be apparent to those skilled in the art that various modifications and variations can be made to the disclosed embodiments. It is intended that the specification arid examples be considered as exemplary only, with a true scope of the disclosure being indicated by the following claims and their equivalents.

1. A semiconductor structure, comprising:
a substrate;
a plurality of sub-array structures disposed on the substrate, the sub-array structures separated from each other by a plurality of trenches;
a three-dimensional array of memory cells, wherein the memory cells comprise a plurality of cell groups disposed in the sub-array structures, respectively;
a plurality of support pillars and a plurality of conductive pillars disposed in the trenches, wherein the support pillars and the conductive pillars in each of the trenches are alternately arranged in an extending direction of the trenches; and
a plurality of conductive lines embedded in the trenches and on the support pillars and the conductive pillars, wherein each of the conductive lines connects the conductive pillars thereunder.

2. The semiconductor structure according to claim 1, wherein the support pillars are formed of an insulating material.

3. The semiconductor structure according to claim 2, wherein the insulating material is an oxide material.

4. The semiconductor structure according to claim 1, wherein each of the conductive pillars comprises a conductive center portion and an insulating liner layer surrounding the conductive center portion.

5. The semiconductor structure according to claim 1, wherein the conductive lines and the conductive pillars are formed of a same material.

6. The semiconductor structure according to claim 1, wherein each of the sub-array structures comprises:
a stack comprising alternately stacked conductive layers and insulating layers; and
one or more active structures penetrating through the stack, each of the one or more active structures comprising:
a channel layer; and
a memory layer disposed between the channel layer and the stack;
wherein the memory cells in the cell group disposed in each of the sub-array structures are defined by cross points between the conductive layers of the stack and the one or more active structures.

7. The semiconductor structure according to claim 6, wherein each of conductive layers comprises two high-k dielectric layers and a conductive core layer disposed therebetween.

8. The semiconductor structure according to claim 6, wherein each of the sub-array structures further comprises:
one or more conductive pads coupled to the one or more active structures, respectively.

9. The semiconductor structure according to claim 8, wherein the conductive layers of the stacks of the sub-array structures are configured for word lines, the conductive pads of the sub-array structures are configured for bit lines, and the conductive pillars and the conductive lines are configured for common source lines.

10. The semiconductor structure according to claim 6, wherein the each of the sub-array structures further comprises:
an interlayer dielectric layer disposed on the stack.

11. A method for manufacturing a semiconductor structure, comprising:
providing an initial structure, wherein the initial structure comprises a substrate and a preliminary array structure formed on the substrate, the preliminary array structure comprises a stack and a plurality of active structures penetrating through the stack, and each of the active structures comprises a channel layer and a memory layer formed between the channel layer and the stack;
forming a plurality of support pillars in predetermined trench positions for a plurality of trenches configured for separating the preliminary array structure into a plurality of sub-array structures, wherein the support pillars are separated from each other in each of the predetermined trench positions;
forming a plurality of conductive pillars in the predetermined trench positions such that the conductive pillars and the support pillars in each of the predetermined trench positions are alternately arranged in an extending direction of the predetermined trench positions; and
forming a plurality of conductive lines on the support pillars and the conductive pillars.

12. The method according to claim 11, wherein forming the support pillars comprises:
forming a plurality of first openings in the predetermined trench positions; and
filling a first insulating material into the first openings.

13. The method according to claim 12, wherein the first insulating material is an oxide material.

14. The method according to claim 12, wherein forming the conductive pillars comprises:
after forming the support pillars, forming a plurality of second openings in the predetermined trench positions between the support pillars;
forming insulating liner layers in the second openings, respectively, using a second insulating material; and
filling a first conductive material into the second openings.

15. The method according to claim 14, wherein the first conductive material is also used to form the conductive lines.

16. The method according to claim 14, wherein the stack comprises alternately stacked sacrificial layers and insulating layers.

17. The method according to claim 16, further comprising:
replacing the sacrificial layers with conductive layers, comprising:
removing the sacrificial layers through the second openings;
forming high-k dielectric layers on top sides and bottom sides of the insulating layers; and
filling a second conductive material into remaining portions of spaces produced by removing the sacrificial layers.

18. The method according to claim 17, wherein the preliminary array structure further comprises:
a plurality of conductive pads coupled to the active structures, respectively.

19. The method according to claim 18, wherein the conductive layers are configured for word lines, the conductive pads are configured for bit lines, and the conductive pillars and the conductive lines are configured for common source lines.

20. The method according to claim 16, wherein the preliminary array structure further comprises:
an interlayer dielectric layer formed on the stack
